(19) United States
(12) Patent Application Publication
(10) Pub. No.: US 2004/0258118 A1
(43) Pub. Date: Dec. 23, 2004

(54) Semiconductor laser and method of increasing its tunable range of wavelength by rearranging the configuration of quantum well structures

(75) Inventors: Ching-Fuh Lin, Taipei (TW); Yi-Shin Su, Dali City (TW)

Correspondence Address: Bo-In Lin, 13445 Mandoli Drive, Los Altos Hills, CA, 94022, US

(73) Assignee: National Taiwan University

(21) Appl. No.: 10/729,657

(22) Filed: Dec. 5, 2003

(30) Foreign Application Priority Data
Jun. 20, 2003 (TW) 92116754

(51) Int. Cl. H01S 5/00; H01S 3/10

(52) U.S. Cl. 372/43; 372/20

(57) ABSTRACT

Disclosed is a method of increasing the tunable range of wavelength of a semiconductor laser by rearranging the configuration of the semiconductor laser and the semiconductor laser formed thereby. Such method uses a specific arrangement of quantum well structures to minimize the diversity between the electron distribution and the hole distribution within the quantum well structures, and a uniform carrier distribution can be obtained within the quantum well structures. Accordingly, each quantum well structure is able to receive carrier and a better luminescent bandwidth can be produced, and the tunable range of wavelength of the semiconductor laser can be extended to a wide extent. Such method is quite convenient for testing semiconductor laser device. Furthermore, such method can also be applied in an optical communication system to replace other versatile components, and thus reduce the cost necessary for system integration.

### BACKGROUND OF THE INVENTION

1. Field of the Invention

The present invention is related to a wavelength-tunable semiconductor laser, and more particularly to a wavelength-tunable semiconductor laser having a larger tunable range of wavelength attained by rearranging the configuration of quantum well structures.

2. Description of the Related Art

With the prosperity of the Internet age, transmitters, receivers or switchers that are indispensable for an optical fiber network have made themselves the keys in the photoelectric-related research study. Because a photoelectric semiconductor device is characterized in terms of a thin-and-small volume, capability of generating optical signals of high luminescent power, high switching speed, and high stability (including durability against temperature variation and long operating time), it has been generally acknowledged as an essential element for optical fiber communication.

For example, semiconductor laser acts as an essential light source for an optical fiber network, and a wavelength-tunable semiconductor laser is of particular importance for a broadband optical fiber communication system. Wavelength-tunable semiconductor laser having a large gain bandwidth is applicable to system test program and component test process, and even it can be applied in an optical fiber communication system for reducing the cost of stock management and network layout scheme. On the other hand, although an Er-doped fiber amplifier (hereinafter “EDFA”) has been commonly used for the amplification of the optical relay signal in an optical communication system, its available bandwidth is still limited and confined between C-band and L-band (1525 nm-1605 nm). However, the optical signal transmitted using another important band (around 1300 nm) in the optical fiber communication can scarcely be amplified by EDFA. In this manner, the future optical communication system can not rely upon EDFA solely.

Referring to FIG. 1, an absorption spectrum of the current optical fiber is shown. As indicated in FIG. 1, the solid curve located in the bottom represents a single mode optical fiber with 4% germanium dioxide (GeO₂) doped in its core portion, while the dashed curve located in the top represents a multi mode optical fiber. The peak value of the attenuation located in correspondence with the wavelength of 1400 nm or so is emerged because of the presence of water molecules in the optical fiber glass. This absorption peak has been removed by the new technology pioneered by Lucent Technology at 2000, and therefore the optical fiber can provide a low loss transmission over a wide range of wavelength from 1250 mm to 1650 nm.

The fabrication technique of the optical fiber today is continuously improving its completeness with each passing day, and the usable frequency band of optical communication system has covered the range from 1200 nm to 1650 nm. However, although EDFA has a better coupling efficiency with optical fiber, it only provides a limited gain bandwidth. In the range of wavelength of C-band and L-band, EDFAs with different gain bandwidths are necessarily required, and the costs of stock management and fabrication are prohibitive accordingly. These disadvantageous factors pertinent to EDFA have been considered as one of the major drawbacks as it is employed in an optical fiber communication system. What is worse, the frequency band in the proximity of 1300 nm is incompatible with any kind of EDFA. As a result, if it is intended to use a semiconductor optical amplifier as the repeater in an optical fiber communication system, it had better to be able to provide a robust and sufficient gain as its luminescent bandwidth lies between 1250 nm and 1650 nm. Unfortunately, the conventional photoelectric semiconductor device only can provide a luminescent bandwidth of 40 nm or so, which is unsatisfactory for broadband optical fiber communication system.

The recent research report points out that the carriers excited by current injection do not result in a uniform distribution in multi-layer quantum well structures. If it is desired to increase the gain bandwidth, i.e. increase the luminescent bandwidth of a semiconductor optical amplifier, the effect of non-uniform carrier distribution has to be taken into consideration. In the past, some scientists attempt to increase the luminescent bandwidth of a photoelectric semiconductor device by using asymmetrical multi-layer quantum well structures. A distinct example of the prior research achievement is given in U.S. Pat. No. 6,014,250 issued to Granestrand. Early to the filing of this patent, Milkami proposed a measure of increasing the luminescent bandwidth of a semiconductor photoelectric device in an article published in Appl. Phys. Lett. 56, pp. 987-989, 1990. Both of these prior art literatures are incorporated herein. However, the effect of non-uniform carrier distribution was never taken into consideration. These prior exertions did not make fruitful achievements after all.

In consideration of the deficiencies encountered by the prior art, the present invention presents a semiconductor laser and method of increasing the tunable range of wavelength of the semiconductor laser by rearranging the configuration of the semiconductor laser. The technique of the present invention employs two different quantum well structures such that the energy levels of each quantum well structure of the semiconductor laser can engage with one another. Further, the present invention takes the property of non-uniform carrier distribution within quantum well structures into consideration, in order that uniform carrier distribution can be made within each different quantum well structure, and an ultra-wide luminescent bandwidth can be obtained. The tunable range of wavelength of the semiconductor laser manufactured thereby can cover a very large bandwidth from 1250 nm to 1650 nm.

### SUMMARY OF THE INVENTION

A first object of the present invention is to provide a semiconductor laser and a method of increasing the tunable range of wavelength of a semiconductor laser by rearranging the configuration of quantum well structures, wherein the tunable range of wavelength of the semiconductor laser can be extended to a wide extent, and is adapted for system test procedure in an optical communication system. The semiconductor laser of the present invention can be directly integrated with an optical communication system and replace other versatile components in the optical communication system in order to reduce the cost necessary for system integration.

Another object of the present invention is to provide a semiconductor laser and a method of increasing the tunable range of wavelength of a semiconductor laser by rearranging the configuration of quantum well structures, and further it is directed to the technique of increasing the luminescent bandwidth of a semiconductor photoelectric device through the use of quantum well structures having different widths, with the result that either electrons or holes serving as the dominant carrier is able to control the two-dimensional carrier distribution within the quantum well structures, and a larger gain bandwidth and a better temperature coefficient can be obtained accordingly.

A practical aspect of the preset invention is to provide a semiconductor laser having an increased tunable range of wavelength attained by rearranging the configuration of quantum well structures, including a semiconductor substrate and at least two quantum well structures formed thereon, each of the quantum well structures has a different luminescent wavelength, and if the sum of the hole diffusion time plus the hole capture time is greater than the sum of the electron diffusion time plus the electron capture time, the quantum well structures must be arranged in such a manner that the quantum well structure located in the proximity of P-type semiconductor side has a relatively high two-dimensional density of states. If the sum of the electron diffusion time plus the electron capture time is greater than the sum of the hole diffusion time plus the hole capture time, the quantum well structures must be arranged in such a manner that the quantum well structure located in the proximity of N-type semiconductor side has a relatively high two-dimensional density of states, in order that a uniform carrier distribution can be produced.

Another practical aspect of the present invention is to provide a method of increasing the tunable range of wavelength of a semiconductor laser by rearranging the configuration of quantum well structures of the semiconductor laser. The method includes the steps of providing a semiconductor substrate having at least two quantum well structures formed thereon and each of the quantum well structures has a different luminescent wavelength. Further, the method takes the arithmetic result of the comparison between the sum of the hole diffusion time plus the hole capture time and the sum of the electron diffusion time plus the electron capture time to determine whether the configuration of the quantum well structures is to be fixed by allowing the quantum well structure located in the proximity of P-type semiconductor side or N-type semiconductor side has a relatively high two-dimensional density of states, and thereby produce a uniform carrier distribution within quantum well structures.

The foregoing and features and advantages of the present invention will become more apparent through the following descriptions with reference to the accompanying drawings, in which:

### BRIEF DESCRIPTION OF THE DRAWINGS

FIG. 1 is an absorption spectrum of the current optical fiber.

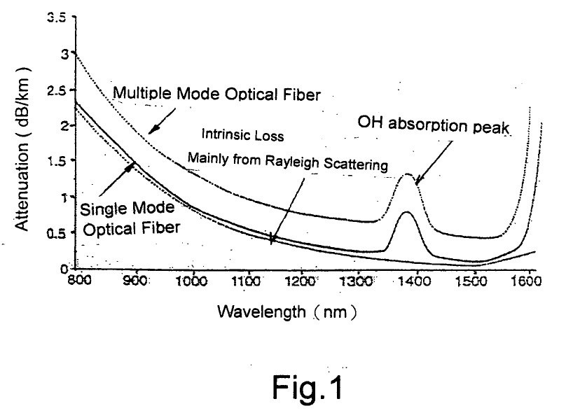

FIG. 2 is a characteristic plot illustrating the relationship between the energy of the quantum well structures and the density of states.

FIG. 3 show the epitaxy structure of the quantum well structures being constructed with arrangement A.

FIG. 4 show the epitaxy structure of the quantum well structures being constructed with arrangement B.

FIG. 5 shows the epitaxy structure of the quantum well structures being constructed with arrangement C.

FIG. 6 shows the relationship between the threshold current and wavelength of quantum well structures being constructed with the above three arrangements in an external-cavity laser element.

FIG. 7 illustrates the tunable spectrum of the epitaxial quantum well structures in an external-cavity laser element.

FIG. 8 illustrates the relationship between the threshold current and wavelength of a ridge waveguide laser diode fabricated from the quantum well structures being constructed with arrangement A in an external-cavity laser element.

### DETAILED DESCRIPTION OF THE INVENTION

Considering a semiconductor laser, it is not possible to ensure the increment of its luminescent bandwidth simply by way of multi-layer quantum well structures, and what is more, the characteristic of non-uniform carrier distribution within the multi-layer quantum well structures has to be taken into consideration. The carrier distribution within multi-layer quantum well structures is quite non-uniform, and will vary drastically depending on the configuration, arrangement and composition of multi-layer quantum well structures. During the design stage of semiconductor laser, these variable factors have to be taken into consideration. As a result, it is intended to dwell on the factors that are to be taken into consideration during the design stage of multi-layer quantum well structures for an ultra-wideband framework first, and the way of how to fit the purpose of increasing the gain bandwidth of a semiconductor laser by rearranging the configuration of the quantum well structures in compliance with the density of states of quantum well structures will be described later. By using the teachings disclosed herein, the configuration of the multi-layer quantum well structures that is capable of increasing the gain bandwidth of a semiconductor laser and further increasing the tunable range of wavelength of a wavelength-tunable semiconductor laser can be disposed.

To design multi-layer quantum well structures having different widths for ultra-wideband communication, the following aspects should be synthetically considered:

1. The energy levels of quantum wells having the same width: The purpose of designing a semiconductor laser for use in broadband communication can be achieved by accommodating desirable luminescent wavelengths by stacking multi-layer quantum well structures having different widths. However, the following situations should be considered:

a. If the quantum well bottoms and the materials of the barriers of these quantum wells having different widths are identical with each other, it can be understood according to the deduction from quantum physics that the quantum well structures having a large width occupy a low quantized energy level and a long luminescent wavelength. On the contrary, the quantum well structures having a small width occupy a high quantized energy level and a short luminescent wavelength. The result reveals that if it is required to achieve the same gain value, the quantum well structures having a large width require a low carrier concentration according to the detailed calculation result derived based on the gain spectrum. However, this would impact the final luminescent spectrum.

b. If the quantum well bottoms or barriers of multi-layer quantum well structures are made of different materials, the flexibility of design can be aggrandized. That is, one may design multi-layer quantum well structures having different luminescent wavelengths and similar quantized energy levels. In this way, the gain bandwidth can be increased effectively, and the gain values are quite unanimous with each other as the gain value is positive.

c. If the fact that the radiations from quantum well structures having a high quantized energy level occupies a high energy, and it is prone to be reabsorbed by quantum well structures having a low quantized energy level is taken into consideration, the number of quantum well structures having a high energy level should be set more when the number of the multi-layer quantum well structures having different widths are to be determined during design stage. However, the actual allocation of the number of the multi-layer quantum well structures should be determined according to the calculation result derived based on the gain spectrum.

2. The length of the SCH structure: In a quantum well structure, the electron-hole pairs that are excited by current injection are injected from P and N junctions respectively, and then enter the active region via separate confinement heterostructures and recombine here to emit lights therefrom. Hence, the mobility of the carrier in SCH region governs its ability to control the two-dimensional carrier distribution within the quantum well structures.

a. If electrons enter the quantum well structures earlier, electrons will become the dominant carrier controlling the two-dimensional carrier distribution within the quantum well structures. The final two-dimensional carrier distribution within the quantum well structures depends on the spatial distribution of electrons (since the electrons are injected into the quantum well through N junction, the concentration of electrons will be high in the proximity of N junction) and will be allocated correspondingly according to the charge neutrality principle. The same theorem may apply when holes are the dominant carriers. The following arithmetic model can be used to determine which carrier is the dominant carrier:

$$\begin{matrix}{τ}_{LF} = {τ}_{p , diffusion} + {τ}_{n , diffusion} + {τ}_{cap , p} + {τ}_{cap , n} \\ = \frac{{d}_{p}^{2}}{4 {D}_{p}} + \frac{{d}_{n}^{2}}{4 {D}_{n}} + \frac{{d}_{p} {τ}_{cp}}{W} + \frac{{d}_{n} {τ}_{cn}}{W}\end{matrix}$$

where dₚ(dₙ) stands for the distance that the hole (electron) diffused to the quantum well, i.e. the length of the SCH region, Dₚ and Dₙ stand for the diffusion coefficients of semiconductor material, W is the width of the quantum well structures, and dₚτ_{cp} and dₙτ_{cn} are respectively the electron capture time and hole capture time according to the calculation result derived based on quantum physics. Therefore, the four temporal variables located on the left side of the equal sign respectively denote the hole diffusion time in the SCH region, the electron diffusion time in the SCH region, the equivalent hole capture time of the quantum well structures, and the equivalent electron capture time of the quantum well structures. Moreover, in order to take the adverse effect that the electrons that are not captured by the quantum well structures will accumulate in the SCH region and prolong the diffusion time into account, the equivalent carrier capture time of the quantum well structures should be equal to the product of the carrier capture time by the quantum well structures multiplied by a volume ratio of dₚ(dₙ)/W.

b. The temporal variables associated with holes in the above equation (the hole diffusion time+the equivalent hole capture time) are defined as the time between the holes injecting into the SCH region and being captured by the quantum well structures to enter the two-dimensional energy level τ_{p,total}=τ_{p,diffision}+τ_{cap,p}, and it is to be compared with the time between the electrons injecting into the SCH region and being captured by the quantum well structures to enter the two-dimensional energy level τ_{n,total}=τ_{n,diffusion}+τ_{cap,n} (the electron diffusion time+the equivalent electron capture time). If τ_{p,total}>τ_{n,total}, the electrons will enter the two-dimensional energy level of the quantum well structures earlier, and the concentration of electrons in the proximity of N-type semiconductor side is high. The holes that enter the two-dimensional energy level of the quantum well structures later will present similar distribution according to the distribution of electrons. Thus, the concentration of two-dimensional carriers within the quantum well structures in the proximity of N-type semiconductor side is high. On the contrary, if τ_{n,total}>τ_{p,total}, the holes will enter the two-dimensional energy level of the quantum well structures earlier, and the concentration of holes in the proximity of P-type semiconductor side is high. The electrons that enter the two-dimensional energy level of the quantum well structures later will present similar distribution according to the distribution of holes. Thus, the concentration of two-dimensional carriers within the quantum well structures in the proximity of P-type semiconductor side is high. In comparison between the two foregoing situations, if holes are selected as the dominant carrier, its great equivalent mass will debase its temperature sensitivity, resulting in a better temperature coefficient. On the contrary, if electrons are selected as the dominant carrier, the carrier distribution within the quantum well structures will be even uniform, resulting in a larger gain bandwidth.

c. The uniformity of carriers within the quantum well structures: The uniformity of carriers within the quantum well structures is related to the carrier capture rate in quantum well structures, namely, the capability of the quantum well structures in capturing carriers is connected with the two-dimensional density of states of the quantum well structures. The higher the two-dimensional density of states of the quantum well structures is, the better the capability of the quantum well structures in capturing carriers is. The carrier distribution within the quantum well structures having different widths can be affected based on the uniformity of carrier distribution within the quantum well structures as well as the selection of dominant carrier. If a large luminescent bandwidth is desired, the carriers have to distribute uniformly within the quantum well structures having different widths. However, this would sacrifice some luminescent properties of such photoelectric device, for example, the luminescent efficiency.

d. The following factors would impact the uniformity of carrier distribution within quantum well structures:

1. The composition of quantum well bottom and barrier, the width of quantum well structures, and the arrangement of the quantum well structures having different widths: According to experimental analysis, the composition of the quantum well bottom and barrier will affect the capability of the quantum well structures in confining the carriers based on the two-dimensional and three-dimensional density of states, and bring influence on the final two-dimensional carrier distribution (including the selection of dominant carrier). The width of the quantum well structure will influence the two-dimensional density of states of the quantum well structure, and further influence the carrier distribution and uniformity of carrier distribution within the quantum well structure.

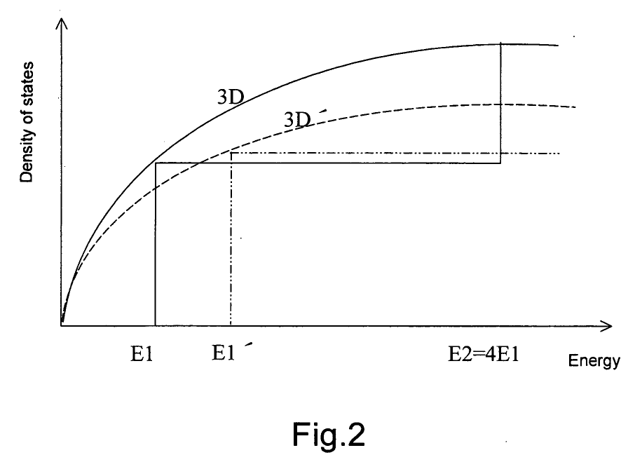

FIG. 2 is a characteristic plot illustrating the relationship between the energy of the quantum well structures and the density of states. As shown in this plot, different parabolas represent different semiconductor materials, i.e. the energy levels of the quantum well structures form step functions under different three-dimensional energy level densities. Parabolas 3D and 3D′ denotes different semiconductor materials, and E1 and E1′ denote different widths of quantum well structures. If the quantized energy levels of the quantum well structures are almost the same with each other, the difference between the two-dimensional energy level densities mainly comes from the difference between the substantial composition. Further, the density of states is influential in the uniformity of two-dimensional carrier distribution. It can be understood that the two-dimensional density of states has a familiar relationship with the width and the composition of quantum well structures, and these factors have to be taken into consideration in the design stage.

2. The width and height of barrier: In multi-layer quantum well structures, the wider the barrier between the quantum wells is, the better uniformity the carrier distribution within the multi-layer quantum well structures has, the lower the barrier between quantum well structures is, and the better uniformity the two-dimensional carrier distribution within the quantum well structures has.

3. The width of SCH region: Because the mobility of electrons is far larger than holes, electrons can diffuse to the quantum well structures promptly. In general, the diffusion coefficient of electrons is thirty times larger than that of holes. Although electrons can be captured by the quantum well structures earlier, the capture process will not perform before the electrons reach the quantum well structures. If it is desired to let the electrons and holes to enter the quantum well structures almost at the same time, the time for holes to reach the quantum well structures can not be too much longer than the electron diffusion time to the quantum well structures. Thus, the width of SCH region plays a significant role in determining the diffusion time of the electrons and holes to the quantum well structures. In brief, the sum of the hole diffusion time plus the electron capture time has to be greater than the sum of the electron diffusion time plus the hole capture time. Although the hole capture time is shorter than the electron capture time, holes are likely to reach the quantum well structures later than the electrons for 10 picoseconds. Even though the hole capture time is very short (can be shorter than 1 picosecond), the sum of the hole diffusion time plus the electron capture time is still far greater than the sum of the electron diffusion time plus the electron capture time, and the electron is selected as the dominant carrier in the quantum well structures, resulting in a non-uniform carrier distribution within the quantum well structures. The width of the SCH region has to be appropriately selected to effect the criterion that the sum of the electron diffusion time plus the electron capture time is approximately equal to the sum of hole diffusion time plus the hole capture time.

4. The effect of dopant ion diffusion: When a semiconductor device is doped into a P-type semiconductor, the dopant ions are apt to diffuse. They may penetrate into the quantum well structures during epitaxy process or manufacturing process, which in turn lower the gain value provided by the quantum well structures located in the proximity of P-type semiconductor side. Therefore, the adverse effects caused by dopant ion diffusion have to be eliminated.

5. The configuration of quantum well structures: If the above-described factors are sufficient to provide a uniform carrier distribution within quantum well structures, the configuration of the quantum well structures is not so important. In fact, however, the above-described factors are insufficient to provide a uniform carrier distribution within quantum well structures on occasion. Under such condition, the rearrangement of the configuration of quantum well structures is suitable for the improvement of the uniformity of the carrier distribution within quantum well structures.

Since the semiconductor laser for ultra-wideband application would be affected by a plethora of factors, the present invention is concentrated on the provision of a technique of increasing the tunable range of wavelength of a semiconductor laser by rearranging the configuration of quantum well structures in compliance with the density of states of the quantum well structures.

The semiconductor laser and the method of increasing the tunable range of wavelength of the semiconductor laser according to the present invention is based the rationale of: providing a semiconductor laser, in which at least two quantum well structures of different type are formed on a semiconductor, each of the quantum well structures has a different luminescent wavelength and includes at least one quantum well. If the sum of hole diffusion time plus hole capture time is larger than the sum of electron diffusion time plus electron capture time, electrons become the dominant carrier and the carrier distribution is biased toward the quantum well structure located in the proximity of the N-type semiconductor side. Meanwhile, if the quantum well structure located in the proximity of the P-type semiconductor side is made of a semiconductor material with a relatively large two-dimensional density of states which provides a stronger capture capability for carriers, the carriers will also be distributed in the proximity of P-type semiconductor side and the bias of carrier distribution can be eliminated. In this manner, all the quantum well structures can make a contribution to the gain value, and thereby increase bandwidth. Therefore, the arrangement of the configuration of quantum well structures in this example depends on the status that the quantum well structure located in the proximity of P-type semiconductor side has a relatively large two-dimensional density of states. On the contrary, if the sum of electron diffusion time plus electron capture time is larger than the sum of hole diffusion time plus hole capture time, holes become the dominant carrier and carrier distribution is biased toward the quantum well structure located in the proximity of the P-type semiconductor side. Meanwhile, if the quantum well structure located in the proximity of the N-type semiconductor side is made of a semiconductor material with a relatively large two-dimensional density of states which provides a stronger capture capability for carriers, the carriers will also be distributed in the proximity of N-type semiconductor side and the bias of carrier distribution can be eliminated. In this manner, all the quantum well structures can make a contribution to the gain value, and thereby increase bandwidth. Therefore, the arrangement of the configuration of quantum well structures in this example depends on the status that the quantum well structure located in the proximity of N-type semiconductor side has a relatively large two-dimensional density of states.

The two-dimensional density of states of a semiconductor laser is strongly related the width and composition of quantum well structures, and thereby multiple quantum well structures of different types and luminescent wavelengths can be stacked together to form a semiconductor laser. When the composition of each quantum well structure is different from each other, the capability of quantum well structures in confining carriers will be affected by the relationship between the composition and two-dimensional density of states, and further the final two-dimensional carrier distribution will be affected. Moreover, the two-dimensional density of states is calculated based on the energy band structure of each constituent component, and is derived from the density of the first energy level of the quantum well structure. When each of the quantum well structures has a different width with each other, the width of the quantum well structure will affect two-dimensional density of states of the quantum well structures, and further affect the carrier distribution and the uniformity of carrier distribution within the quantum well structures. Such two-dimensional density of states is calculated based on the energy band structure of each constituent component, and is derived from the density of the first energy level of the quantum well structure.

Second, if the quantum well structures are designed by using different semiconductor materials and different width specifications, the difference between the two-dimensional energy level densities between the quantum well structures mainly ascribes to the difference between the composition of the quantum well structures. Also, the density of states will affect the capability of carrier capture and the uniformity of two-dimensional carrier distribution.

The quantum well structures are adapted for III-V semiconductors used in an optical communication system. The quantum well structures may be made of one of the semiconductor materials including II-VI semiconductors, IV semiconductors, the compound of IV semiconductors and III-V semiconductors, the compound of IV semiconductors and II-VI semiconductors, the compound of III-V semiconductors and II-VI semiconductors, and the compound of IV semiconductors, III-V semiconductors and II-VI semiconductors, and alternatively may be made of two or more chemical elements.

In addition, the above equation may be applied to determine whether electrons or holes serve as the dominant carrier within the quantum well structures according to the present invention. If τ_{p,total}>τ_{n,total}, electrons will enter the two-dimensional energy level earlier, and a high concentration of electrons will be induced in the proximity of N-type semiconductor side. The holes that enter the two-dimensional energy level of quantum well structures later will be distributed in a similar manner as the electron distribution, such that the quantum well structure located in the proximity of N-type semiconductor side has a relatively high two-dimensional density of states. As a result, the quantum well structure located in the proximity of P-type semiconductor side must have a relatively high two-dimensional density of states when the arrangement of the configuration of quantum well structures is considered during design stage. If τ_{n,total}>τ_{p,total}, holes will enter the two-dimensional energy level earlier, and a high concentration of the holes will be induced in the proximity of P-type semiconductor side. The electrons that enter the two-dimensional energy level of quantum well structures later will be distributed in a similar manner as the hole distribution, such that the quantum well structure located in the proximity of P-type semiconductor side has a relatively high two-dimensional density of states. As a result, the quantum well structure located in the proximity of N-type semiconductor side must have a relatively high two-dimensional density of states when the arrangement of the configuration of quantum well structures is considered during design stage.

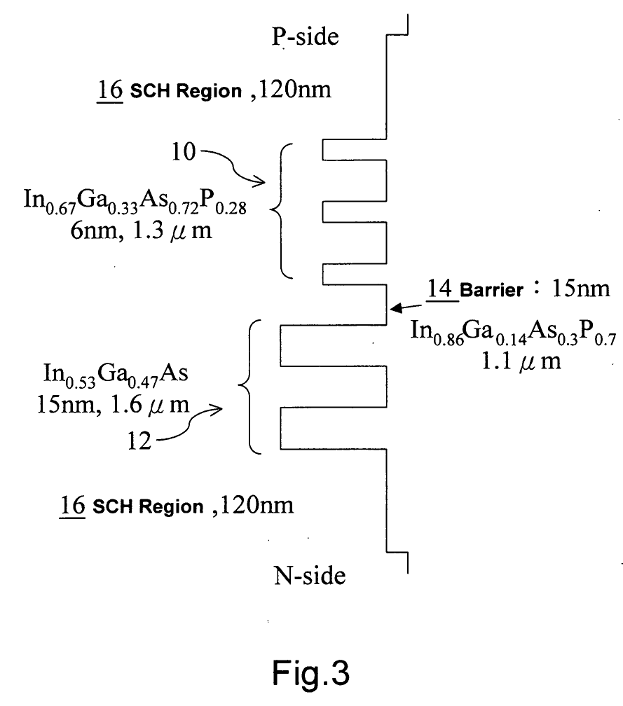

In order to testify the influence of the arrangement of quantum well structures on the gain bandwidth, an experiment has been taken to further validate the effectiveness of the present invention. FIGS. 3, 4 and 5 show the epitaxy structure of semiconductor lasers being constructed with three different arrangements. The semiconductor laser of FIGS. 3, 4 and 5 are fabricated by using two different materials and quantum well structures having different width specifications. The semiconductor materials used to form the quantum well structures 10,12 are respectively In_{0.67}Ga_{0.33}As_{0.72}P_{0.2} and In_{0.53}Ga_{0.47}As, and the estimated luminescent wavelength are respectively rated at 1.3 μm and 1.6 μm. The semiconductor material used to form the barrier 14 is In_{0.86}Ga_{0.14}As_{0.3}P_{0.7}. The SCH region 16 has a width of 120 nm.

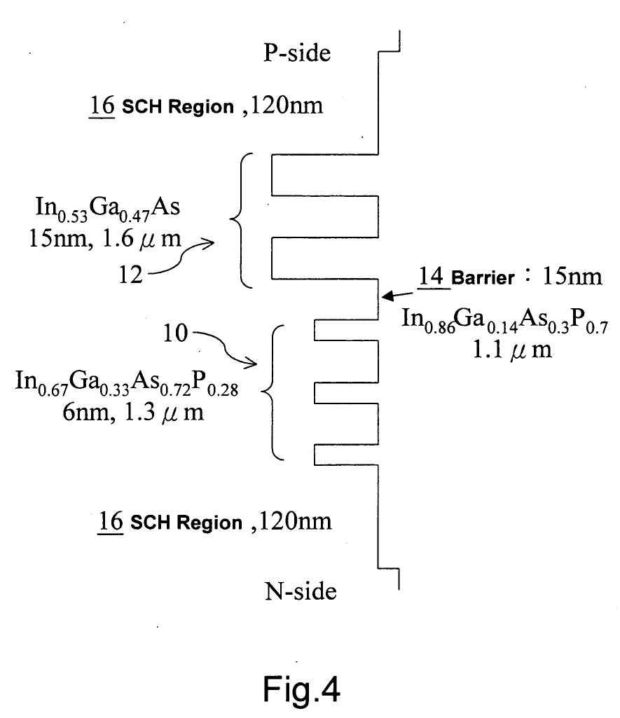

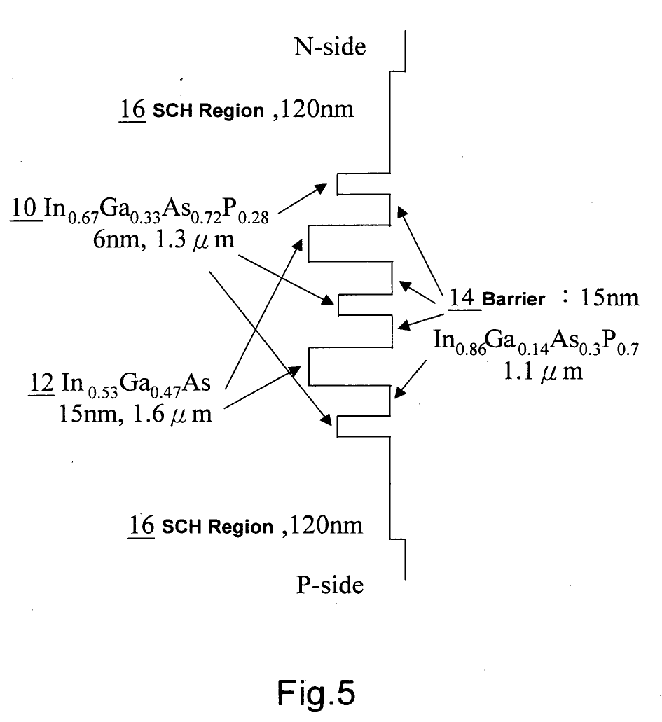

The quantum well structure 10 shown in FIG. 3 is located in the proximity of P-type semiconductor side, and the quantum well structure 12 shown in FIG. 3 is located in the proximity of N-type semiconductor side, and the arrangement of the configuration of quantum well structures of FIG. 3 is named arrangement A. The quantum well structure 10 shown in FIG. 4 is located in the proximity of N-type semiconductor side, and the quantum well structure 12 shown in FIG. 4 is located in the proximity of P-type semiconductor side, and the arrangement of the configuration of quantum well structures of FIG. 4 is named arrangement B. The arrangement of the configuration of quantum well structures 10 and 12 of FIG. 5 is disposed in an interleaved fashion, and is named arrangement C.

The experiment is taken by the steps of fabricating semiconductor optical amplifiers respectively using quantum well structures being constructed with three arrangements described above, and places the semiconductor optical amplifiers in a laser resonant cavity. By using the configuration of an external-cavity laser element, a wavelength-tunable semiconductor laser is established, wherein the wavelength of laser beam can be altered by the rotation of grating. The geometrical structures of these semiconductor optical amplifiers are all shaped into a curved waveguide contour, and their dimensions are the same for the sake of quick comparison.

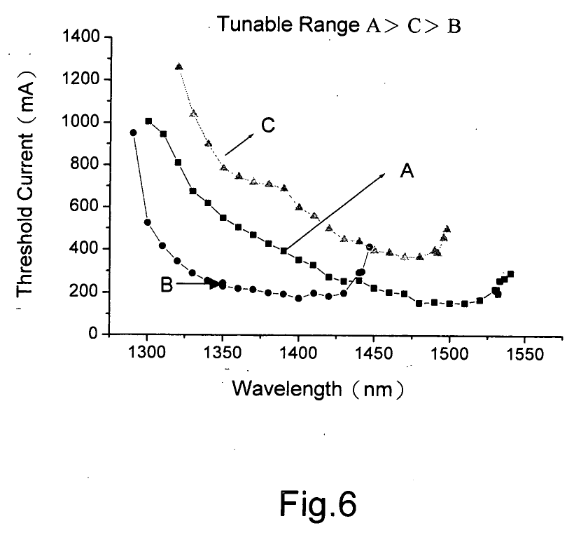

The results of experiment are indicated in FIG. 6. FIG. 6 shows the relationship between the threshold current and wavelength of quantum well structures being constructed with the above three arrangements in an external-cavity laser element. It can be seen from FIG. 6 that the quantum well structure being constructed with arrangement A obtains a widest wavelength and tunable range of wavelength from 1300 nm to 1540 nm. The quantum well structure being constructed with arrangement B which is the reversal of arrangement A obtains a narrowest tunable range of wavelength from 1290 nm to 1450 nm. The quantum well structure being constructed with arrangement C obtains a middle tunable range of wavelength from 1320 nm to 1500 nm, which lies between the tunable ranges of wavelength of other experiment samples.

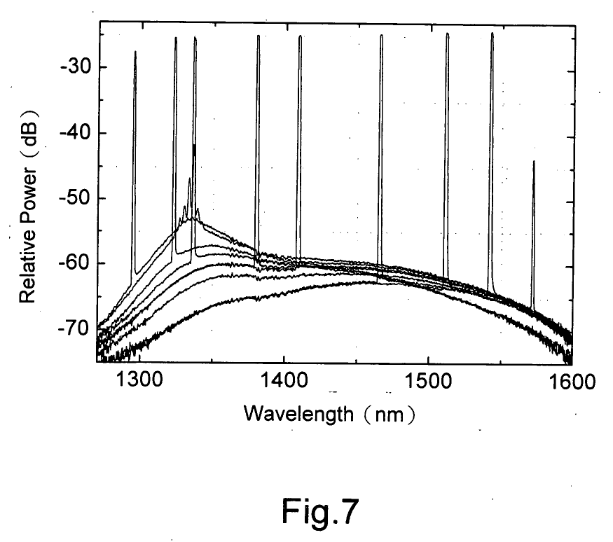

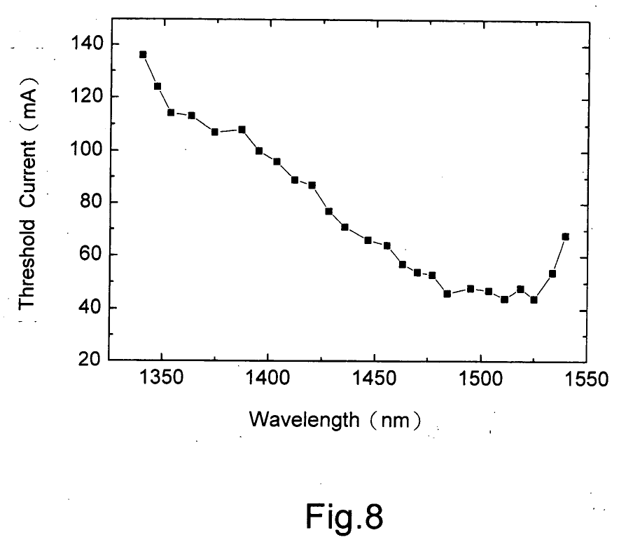

The quantum well structure being constructed with arrangement A is further experimented as follows. A semiconductor optical amplifier is formed by a waveguide-based Fabry-Perot laser diode forms through an anti-reflection coating, and a wavelength-tunable laser having a tunable range of wavelength from 1295 nm to 1570 nm is produced by using an external-cavity laser topology. The result of experiment is shown in FIG. 7, wherein the tunable range of wavelength is rated at 275 nm. However, a wavelength-tunable laser can be produced by an external-cavity laser topology using a waveguide-based Fabry-Perot laser diode without an anti-reflection coating. In case of a narrower waveguide width, the required current is significantly reduced. The relationship of the threshold current versus wavelength is illustrated in FIG. 8. As depicted in FIG. 8, the threshold current is lower than 10 mA if the range of wavelength is limited within 200 nm. It is noted that the above experiments and examples are intended to be taken as embodiments of the present invention. If the manufacturing process of semiconductor laser is further improved, the tunable range of the semiconductor laser can be further extended by using quantum well structures with a more appropriate configuration in consideration of the same arrangement.

In conclusion, the wavelength-tunable semiconductor laser and method of increasing the tunable range of wavelength of the semiconductor laser according to the present invention is attained by appropriately arranging the configuration of quantum well structures of the semiconductor laser, which can fulfill the desired performance in an optical communication system.

Consequently, it is appreciated that the present invention utilizes the method of rearranging the configuration of quantum well structures in compliance with the density of states of the quantum well structures to achieve an even uniform carrier distribution within the quantum well structures and fulfill the demand of increasing the gain bandwidth and tunable range of wavelength of a semiconductor laser. Since the tunable range of wavelength of a semiconductor laser is extended to a wide extent, it can be integrated with an optical communication system and replace other versatile components to reduce the cost necessary for system integration.

What is claimed is:

1. A wavelength-tunable semiconductor laser, comprising:
a semiconductor substrate; and
at least two types of quantum well structures formed on the semiconductor substrate, each of which provides a different luminescent wavelength, wherein if the sum of a hole diffusion time plus a hole capture time is larger than the sum of an electron diffusion time plus an electron capture time, the quantum well structures are arranged in a manner that the quantum well structure located in the proximity of a P-type semiconductor side has a relatively high two-dimensional density of states, and if the sum of an electron diffusion time plus an electron capture time is larger than the sum of a hole diffusion time plus a hole capture time, the quantum well structures are arranged in a manner that the quantum well structure located in the proximity of an N-type semiconductor side has a relatively high two-dimensional density of states.

2. The wavelength-tunable semiconductor laser according to claim 1 wherein each type of the quantum well structures includes at least one quantum well.

3. The wavelength-tunable semiconductor laser according to claim 2 wherein each type of the quantum well structures is formed from different materials.

4. The wavelength-tunable semiconductor laser according to claim 3 wherein if each type of the quantum well structures is differentiated from one other in terms of different composition, a two-dimensional density of states of the quantum well structures is calculated based on the energy band structures of each constituent material of the quantum well structures, and is derived from a first quantized density of states of the quantum well structures.

5. The wavelength-tunable semiconductor laser according to claim 1 wherein each type of the quantum well structures has a different width.

6. The wavelength-tunable semiconductor laser according to claim 5 wherein if each type of the quantum well structures is differentiated from one other in terms of different width, a two-dimensional density of states of the quantum well structures is calculated based on the energy levels of the quantum well structures, and is derived from a first quantized density of states of the quantum well structures.

7. The wavelength-tunable semiconductor laser according to claim 1 wherein different luminescent wavelengths are obtained by stacking quantum well structures of different types based on the difference between the energy levels of the quantum well structures.

8. The wavelength-tunable semiconductor laser according to claim 1 wherein the following arithmetic model is used to determine which carrier is the dominant carrier:
$$\begin{matrix}{τ}_{LF} = {τ}_{p , diffusion} + {τ}_{n , diffusion} + {τ}_{cap , p} + {τ}_{cap , n} \\ = \frac{{d}_{p}^{2}}{4 {D}_{p}} + \frac{{d}_{n}^{2}}{4 {D}_{n}} + \frac{{d}_{p} {τ}_{cp}}{W} + \frac{{d}_{n} {τ}_{cn}}{W}\end{matrix}$$
where dₚ and dₙ respectively represents the distance that the hole or electron diffused to the quantum well structures, Dₚ and Dₙ represent the diffusion coefficients of semiconductor material, W represents the width of the quantum well structures, dₚτ_{cp} and dₙτ_{cn} respectively represent the electron capture time and hole capture time according to the calculation result derived based on quantum physics, and τ_{p,diffusion}, τ_{cap,p}, τ_{n,diffusion}, and _{cap,n} respectively represent the diffusion time of the holes in the separate confinement heterostructure, the diffusion time of the electrons in the separate confinement heterostructure, the equivalent hole capture time of the multi-layer quantum well structures, and the equivalent electron capture time of the multi-layer quantum well structures, and wherein an equivalent carrier capture time of the quantum well structures is be equal to the product of the carrier capture time of the multi-layer quantum well structures multiplied by a volume ratio of dₚ/W or dₙ/W.

9. The wavelength-tunable semiconductor laser according to claim 8 wherein if τ_{p,total}>τ_{n,total}, electrons are sufficient to enter the two-dimensional energy level of the quantum well structures earlier and thereby result in a higher electron density in the proximity of a N-type semiconductor side, and holes that enter the two-dimensional energy level of the quantum well structures later is similarly distributed according to the distribution of the electrons, so that the two-dimensional carrier distribution in the proximity of the N-type semiconductor side within the multi-layer quantum well structures is relatively high, and the quantum well structures are arranged in a manner that the quantum well structure located in the proximity of a P-type semiconductor side has a relatively high two-dimensional density of states.

10. The wavelength-tunable semiconductor laser according to claim 8 wherein if τ_{n,total}>τ_{p,total}, holes are sufficient to enter the two-dimensional energy level of the quantum well structures earlier and thereby result in a higher hole density in the proximity of a N-type semiconductor side, and electrons that enter the two-dimensional energy level of the quantum well structures later is similarly distributed according to the distribution of the holes, so that the two-dimensional carrier distribution in the proximity of a P-type semiconductor side within the multi-layer quantum well structures is relatively high, and the quantum well structures are arranged in a manner that the quantum well structure located in the proximity of a N-type semiconductor side has a relatively high two-dimensional density of states.

11. The wavelength-tunable semiconductor laser according to claim 8 wherein the uniformity of carrier distribution within the quantum well structures is related to the two-dimensional energy density of the quantum well structures, and the carrier distribution within the quantum well structures is affected according to the determination of the dominant carrier within the quantum well structures.

12. The wavelength-tunable semiconductor laser according to claim 8 wherein the two-dimensional density of states of the quantum well structures is closely related to the width and composition of the quantum well structures, and if the quantum well structures are designed using different semiconductor materials and width specifications and occupy similar quantized energy levels, the difference between the two-dimensional energy level densities is generated from the composition of the quantum well structures, and wherein the two-dimensional density of states of the quantum well structures is influential on the uniformity of carrier distribution within the quantum well structures.

13. The wavelength-tunable semiconductor laser according to claim 1 wherein the composition of the quantum well structures is selected form III-V semiconductors used in an optical communication system.

14. The wavelength-tunable semiconductor laser according to claim 1 wherein the quantum well structures are formed from one group of II-VI semiconductors, III-V semiconductors, and IV semiconductors.

15. A method of increasing a tunable range of wavelength of a semiconductor laser by rearranging the configuration of quantum well structures of the semiconductor laser, the method comprising the steps of:
providing semiconductor laser including at least two types of quantum well structures, each type of the quantum well structures has a different luminescent wavelength; and
if the sum of a hole diffusion time plus a hole capture time is larger than the sum of an electron diffusion time plus an electron capture time, the quantum well structures are arranged in a manner that the quantum well structure located in the proximity of a P-type semiconductor side has a relatively high two-dimensional density of states, and if the sum of an electron diffusion time plus an electron capture time is larger than the sum of a hole diffusion time plus a hole capture time, the quantum well structures are arranged in a manner that the quantum well structure located in the proximity of an N-type semiconductor side has a relatively high two-dimensional density of states.

16. The method according to claim 15 wherein each type of the quantum well structures includes at least one quantum well.

17. The method according to claim 15 wherein each type of the quantum well structures is formed form different materials.

18. The method according to claim 17 wherein if each type of the quantum well structures is differentiated from one other in terms of different composition, a two-dimensional density of states of the quantum well structures is calculated based on the energy band structures of each constituent material of the quantum well structures, and is derived from a first quantized density of states of the quantum well structures.

19. The method according to claim 15 wherein each type of the quantum well structures has a different width.

20. The method according to claim 19 wherein if each type of the quantum well structures is differentiated from one other in terms of different width, a two-dimensional density of states of the quantum well structures is calculated based on the energy levels of the quantum well structures, and is derived from a first quantized density of states of the quantum well structures.

21. The method according to claim 15 wherein different luminescent wavelength is obtained by stacking quantum well structures of different types based on the difference between the energy levels of the quantum well structures.

22. The method according to claim 15 wherein the following arithmetic model is used to determine which carrier is the dominant carrier:
$$\begin{matrix}{τ}_{LF} = {τ}_{p , diffusion} + {τ}_{n , diffusion} + {τ}_{cap , p} + {τ}_{cap , n} \\ = \frac{{d}_{p}^{2}}{4 {D}_{p}} + \frac{{d}_{n}^{2}}{4 {D}_{n}} + \frac{{d}_{p} {τ}_{cp}}{W} + \frac{{d}_{n} {τ}_{cn}}{W}\end{matrix}$$
where dₚ and dₙ respectively represents the distance that the hole or electron diffused to the quantum well structures, Dₚ and Dₙ represent the diffusion coefficients of semiconductor material, W represents the width of the quantum well structures, dₚτ_{cp} and dₙτ_{cn} respectively represent the electron capture time and hole capture time according to the calculation result derived based on quantum physics, and τ_{p,diffusion}, τ_{cap,p}, τ_{n,diffusion}, and _{cap,n} respectively represent the diffusion time of the holes in the separate confinement heterostructure, the diffusion time of the electrons in the separate confinement heterostructure, the equivalent hole capture time of the multi-layer quantum well structures, and the equivalent electron capture time of the multi-layer quantum well structures, and wherein an equivalent carrier capture time of the quantum well structures is be equal to the product of the carrier capture time of the multi-layer quantum well structures multiplied by a volume ratio of dₚ/W or dₙ/W.

23. The method according to claim 22 wherein if τ_{p,total}>τ_{n,total}, electrons are sufficient to enter the two-dimensional energy level of the quantum well structures earlier and thereby result in a higher electron density in the proximity of a N-type semiconductor side, and holes that enter the two-dimensional energy level of the quantum well structures later is similarly distributed according to the distribution of the electrons, so that the two-dimensional carrier distribution in the proximity of the N-type semiconductor side within the multi-layer quantum well structures is relatively high, and the quantum well structures are arranged in a manner that the quantum well structure located in the proximity of a P-type semiconductor side has a relatively high two-dimensional density of states.

24. The method according to claim 22 wherein if τ_{n,total}>τ_{p,total}, holes are sufficient to enter the two-dimensional energy level of the quantum well structures earlier and thereby result in a higher hole density in the proximity of a N-type semiconductor side, and electrons that enter the two-dimensional energy level of the quantum well structures later is similarly distributed according to the distribution of the holes, so that the two-dimensional carrier distribution in the proximity of a P-type semiconductor side within the multi-layer quantum well structures is relatively high, and the quantum well structures are arranged in a manner that the quantum well structure located in the proximity of a N-type semiconductor side has a relatively high two-dimensional density of states.

25. The method according to claim 22 wherein the uniformity of carrier distribution within the quantum well structures is related to the two-dimensional energy density of the quantum well structures, and the carrier distribution within the quantum well structures is affected according to the determination of the dominant carrier within the quantum well structures.

26. The method according to claim 22 wherein the two-dimensional density of states of the quantum well structures is closely related to the width and composition of the quantum well structures, and if the quantum well structures are designed using different semiconductor materials and width specifications and occupy similar quantized energy levels, the difference between the two-dimensional energy level densities is generated from the composition of the quantum well structures, and wherein the two-dimensional density of states of the quantum well structures is influential on the uniformity of carrier distribution within the quantum well structures.

27. The method according to claim 15 wherein the composition of the quantum well structures is selected form III-V semiconductors used in an optical communication system.

28. The method according to claim 15 wherein the quantum well structures are formed from one group of II-VI semiconductors, III-V semiconductors, and IV semiconductors.
